(19) United States
(12) Patent Application Publication
(10) Pub. No.: US 2008/0047603 A1
(43) Pub. Date: Feb. 28, 2008

(54) Front contact with intermediate layer(s) adjacent thereto for use in photovoltaic device and method of making same

(75) Inventor: Alexey Krasnov, Canton, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/509,094

(22) Filed: Aug. 24, 2006

(51) Int. Cl. H01L 31/00

(52) U.S. Cl. 136/256

(57) ABSTRACT

An intermediate film is provided between the front contact and an absorbing semiconductor film of a photovoltaic device. The intermediate film may be discrete or refractive index graded in certain example embodiments of this invention. The refractive index (n) of the intermediate film is tuned to satisfy one or more of: (a) reduce optical reflection of solar radiation from the TCO/absorber interface thereby enhancing the amount of radiation which penetrates the absorber and which can be converted into electrical energy, (b) increase the amount of radiation trapped within the absorber, (c) reduce cross-diffusion of elements between the TCO of the front contact and the absorbing semiconductor film, and/or (d) form a high resistivity buffer layer (HRBL) between the front contact TCO and the absorber film.

This invention relates to a photovoltaic device including a front contact. In certain example embodiments, the front contact of the photovoltaic device includes a glass substrate that supports a transparent conductive oxide (TCO) of a material such as tin oxide, zinc oxide, or the like. An intermediate film is provided between the TCO of the front contact and an absorbing semiconductor film of the photovoltaic device. The intermediate film is designed so as to improve operation efficiency of the photovoltaic device in certain example instances.

### BACKGROUND AND SUMMARY OF EXAMPLE EMBODIMENTS OF INVENTION

Photovoltaic devices are known in the art (e.g., see U.S. Pat. Nos. 6,784,361, 6,288,325, 6,613,603, and 6,123,824, the disclosures of which are hereby incorporated herein by reference). Amorphous silicon photovoltaic devices, for example, include a front contact or electrode. Typically, the transparent front contact is made of a transparent conductive oxide (TCO) such as zinc oxide or tin oxide (e.g., SnO₂:F) formed on a substrate such as a glass substrate. In many instances, the transparent front contact is formed of a single layer using a method of chemical pyrolysis where precursors are sprayed onto the glass substrate at approximately 400 to 600 degrees C. The front contact is typically positioned directly on and contacting an absorbing semiconductor film/layer (including one or more layers) of the device.

Unfortunately, convention photovoltaic devices often reflect significant amounts of incident radiation before such radiation can be converted into electrical energy by the device, thereby leading to inefficient operations.

Thus, it will be appreciated that there exists a need in the art for a photovoltaic device capable of operating in a more efficient manner.

In certain example embodiments of this invention, an intermediate film including at least one layer is provided between the front contact and an absorbing semiconductor film (absorber) of the photovoltaic device. The intermediate film may be discrete or refractive index graded, continuously or discontinuously, in certain example embodiments of this invention. The refractive index (n) of the intermediate film is tuned or designed so as to satisfy one or more of the following: (a) reduce optical reflection of solar radiation from the TCO/absorber interface thereby enhancing the amount of radiation which penetrates the absorber and which can be converted into electrical energy so as to improve efficiency of the device, (b) increase the amount of radiation trapped within the absorber which can be converted into electrical energy, (c) reduce cross-diffusion of elements between the TCO of the front contact and the absorbing semiconductor film, and/or (d) form a high resistivity buffer layer (HRBL) between the front contact TCO and the absorber film.

In certain example embodiments of this invention, the intermediate film may be made of or include a semiconductor material. Being an integrated part of the layer stack of the photovoltaic device, the intermediate film may be a robust anti-reflection (AR) film with additional possible barrier properties.

In certain example embodiments of this invention, there is provided a photovoltaic device comprising: a front glass substrate; a semiconductor film including p-type, n-type and i-type layers; a substantially transparent conductive oxide (TCO) based film located between at least the front glass substrate and the semiconductor film; and an intermediate film located between the TCO based film and the semiconductor film, wherein the intermediate film has a refractive index (n) that is higher than that of the TCO based film and lower than that of the semiconductor film.

In other example embodiments of this invention, there is provided a photovoltaic device comprising: a front glass substrate; a semiconductor absorber film; a substantially transparent conductive oxide (TCO) based film located between at least the front glass substrate and the semiconductor absorber film; and an intermediate film located between the TCO based film and the semiconductor absorber film, wherein the intermediate film has a refractive index (n) of from about 2.0 to 4.0 and which is higher than that of the TCO based film and lower than that of the semiconductor absorber film.

In still further example embodiments of this invention, there is provided a method of making a photovoltaic device, the method comprising: providing a substrate; depositing a first substantially transparent conductive oxide (TCO) film on the substrate; forming an intermediate film on the substrate over at least the TCO film, wherein the intermediate film has a refractive index (n) of from about 2.0 to 4.0 and which is higher than that of the TCO film; and forming the photovoltaic device so that the intermediate film is located between the TCO film and a semiconductor film of the photovoltaic device.

### BRIEF DESCRIPTION OF THE DRAWINGS

FIG. 1 is a cross sectional view of an example photovoltaic device according to an example embodiment of this invention.

FIGS. 2(a), 2(b) and 2(c) are schematic diagrams illustrating improved optical results associated with the intermediate film in certain example embodiments of this invention.

FIG. 3 is a graph illustrating the ratio (G) of the amount of light trapped within the absorbing semiconductor film in a photovoltaic device having an intermediate film according to examples of this invention compared to a device without the intermediate film.

FIG. 4 is a graph illustrating results of using a bi-layer intermediate film according to examples of this invention.

### DETAILED DESCRIPTION OF EXAMPLE EMBODIMENTS OF THE INVENTION

Photovoltaic devices such as solar cells convert solar radiation and other light into usable electrical energy. The energy conversion occurs typically as the result of the photovoltaic effect. Solar radiation (e.g., sunlight) impinging on a photovoltaic device and absorbed by an active region of semiconductor material (e.g., a semiconductor film including one or more semiconductor layers such as a—Si layers) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having n-type conductivity, and holes flow toward the region of the semiconductor having p-type conductivity. Current can flow through an external circuit connecting the n-type region to the p-type region as light continues to generate electron-hole pairs in the photovoltaic device.

In certain example embodiments, single junction amorphous silicon (a—Si) photovoltaic devices include at least three semiconductor layers making up an absorbing semiconductor film. In particular, a p-layer, an n-layer and an i-layer which is intrinsic can make up the absorbing semiconductor film in certain example instances. The amorphous silicon film (which may include one or more layers such as p, n and i type layers) may be of hydrogenated amorphous silicon in certain instances, but may also be of or include hydrogenated amorphous silicon carbon or hydrogenated amorphous silicon germanium, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components. It is noted that while certain example embodiments of this invention are directed toward amorphous-silicon based photovoltaic devices, this invention is not so limited and may be used in conjunction with other types of photovoltaic devices in certain instances including but not limited to devices including other types of semiconductor material, tandem thin-film solar cells, CdS/CdTe based solar cells, and the like.

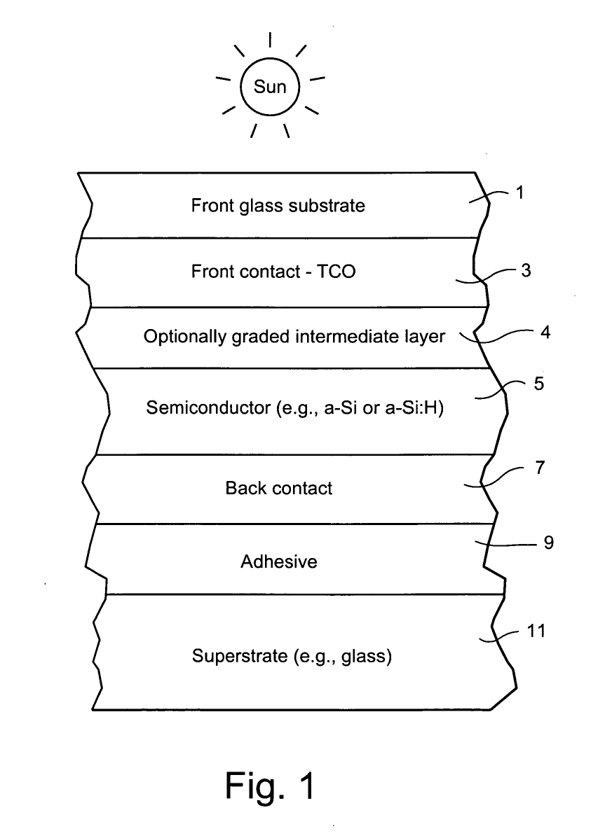

FIG. 1 is a cross sectional view of a photovoltaic device according to an example embodiment of this invention. The photovoltaic device includes transparent front glass substrate 1, front electrode or contact 3 which is of or includes a transparent conductive oxide (TCO) layer 3 such as tin oxide, fluorine-doped tin oxide, zinc oxide, aluminum-doped zinc oxide, indium tin oxide, indium zinc oxide, or the like, intermediate film 4, absorbing semiconductor film 5 of one or more semiconductor layers (e.g., including at least three layers of p, i, and n types), back electrode or contact 7 which may be of a TCO or a metal, an optional encapsulant 9 or adhesive of a material such as ethyl vinyl acetate (EVA) or the like, and an optional superstrate 11 of a material such as glass. Of course, other layer(s) which are not shown may also be provided in the device. Front glass substrate 1 and/or rear superstrate (substrate) 11 may be made of soda-lime-silica based glass in certain example embodiments of this invention. While substrates 1, 11 may be of glass in certain example embodiments of this invention, other materials such as quartz or the like may instead be used. Moreover, superstrate 11 is optional in certain instances. Glass 1 and/or 11 may or may not be thermally tempered and/or patterned in certain example embodiments of this invention. Additionally, it will be appreciated that the word “on” as used herein covers both a layer/film being directly on and indirectly on something, with other layers possibly being located therebetween.

In certain example embodiments of this invention, the photovoltaic device may be made by providing glass substrate 1, and then depositing (e.g., via sputtering or any other suitable technique) TCO 3 on the substrate 1. Then, the intermediate layer 4 is deposited on the substrate 1 over and contacting the TCO 3. Thereafter the structure including substrate 1, front contact 3, and intermediate layer 4 may be coupled with the rest of the device in order to form the photovoltaic device shown in FIG. 1. For example, the semiconductor layer 5 may then be formed over the front contact structure on substrate 1, or alternatively may be formed on the other substrate with the front contact structure thereafter being coupled to the same. Front contact layer 3 and intermediate film 4 are typically continuously, or substantially continuously, provided over substantially the entire surface of the semiconductor film 5 in certain example embodiments of this invention. In certain example embodiments of this invention, the front contact 3 may have a sheet resistance (Rₛ) of from about 7-50 ohms/square, more preferably from about 10-25 ohms/square, and most preferably from about 10-15 ohms/square using a reference example non-limiting overall thickness of from about 1,000 to 2,000 angstroms.

The absorbing or active semiconductor region or film 5 may include one or more layers, and may be of any suitable material. For example, the absorber semiconductor film 5 of one type of single junction amorphous silicon (a—Si) photovoltaic device includes three semiconductor layers, namely a p-layer, an n-layer and an i-layer. The p-type a—Si layer of the semiconductor film 5 may be the uppermost portion of the semiconductor film 5 in certain example embodiments of this invention; and the i-layer is typically located between the p and n-type layers. These amorphous silicon based layers of film 5 may be of hydrogenated amorphous silicon in certain instances, but may also be of or include hydrogenated amorphous silicon carbon or hydrogenated amorphous silicon germanium, or other suitable material(s) in certain example embodiments of this invention. It is possible for the semiconductor region 5 to be of a double-junction type in alternative embodiments of this invention.

Back contact or electrode 7 may be of any suitable electrically conductive material. For example and without limitation, the back contact or electrode 7 may be of a TCO and/or a metal in certain instances. Example TCO materials for use as back contact or electrode 7 include indium zinc oxide, indium-tin-oxide (ITO), tin oxide, and/or zinc oxide which may be doped with aluminum (which may or may not be doped with silver). The TCO of the back contact 7 may be of the single layer type or a multi-layer type in different instances. Moreover, the back contact 7 may include both a TCO portion and a metal portion in certain instances. For example, in an example multi-layer embodiment, the TCO portion of the back contact 7 may include a layer of a material such as indium zinc oxide (which may or may not be doped with silver), indium-tin-oxide (ITO), tin oxide, and/or zinc oxide closest to the active region 5, and the back contact may include another conductive and possibly reflective layer of a material such as silver, molybdenum, platinum, steel, iron, niobium, titanium, chromium, bismuth, antimony, or aluminum further from the active region 5 and closer to the superstrate 11. The metal portion may be closer to superstrate 11 compared to the TCO portion of the back contact 7.

The photovoltaic module may be encapsulated or partially covered with an encapsulating material such as encapsulant 9 in certain example embodiments. An example encapsulant or adhesive for layer 9 is EVA. However, other materials such as Tedlar type plastic, Nuvasil type plastic, Tefzel type plastic or the like may instead be used for layer 9 in different instances.

Intermediate film 4 including at least one layer is provided between the front contact 3 and absorbing semiconductor film (absorber) 5 of the photovoltaic device. The intermediate film 4 may be discrete or refractive index graded, continuously or discontinuously, in certain example embodiments of this invention. The refractive index (n) of the intermediate film 4 is tuned or designed so as to satisfy one or more of the following: (a) reduce optical reflection of solar radiation due to the TCO/absorber interface (i.e., interface between films 4 and 5) thereby enhancing the amount of radiation which penetrates the absorber and which can be converted into electrical energy so as to improve efficiency of the device, (b) increase the amount of radiation trapped within the absorber 5 which can be converted into electrical energy, (c) reduce cross-diffusion of elements between the TCO 3 of the front contact and the absorbing semiconductor film 5 (e.g., to reduce cross diffusion of oxygen and hydrogen between films 3 and 5 in the example case where zinc oxide is used as the TCO 3 and a—Si:H is used in the absorber film 5), and/or (d) form a high resistivity buffer layer (HRBL) in certain cases (e.g., in a CdS/CdTe based solar cell) between the front contact TCO 3 and the absorber film 5 in order to improve device performance.

In certain example embodiments of this invention, the intermediate film 4 may be made of or include a semiconductor material, including but not limited to one or more of Nb-doped anatase TiOₓ, TiOₓ, or the like. In certain example embodiments of this invention, the intermediate film is designed so that all or a portion thereof has a refractive index (n) of from about 2.0 to 4.0, more preferably from about 2.1 to 3.2, and most preferably from about 2.15 to 2.75 (e.g., Nb-doped anatase TiOₓ can be formed so as to have a refractive index n of about 2.4). The intermediate film 4 may or may not be index (n) graded in certain example embodiments of this invention. For instance, when not graded the entire thickness of film 4 has an approximately constant refractive index (n) and an approximately constant chemical make-up through its thickness. However, when graded, the film 4 may be graded in a manner so that its refractive index (n) and/or material make-up changes continuously or discontinuously throughout the film's thickness. For example, in certain example embodiments the film 4 may comprise Nb-doped anatase TiOₓ, where the film 4 is Nb-doped at an area in the film 4 adjacent the TCO 3 but is either not doped or slightly doped at an area in the film 4 adjacent the semiconductor absorber 5, and the refractive index (n) and/or Nb content may vary continuously or discontinuously through the film's thickness or a portion thereof. As another example, the intermediate film 4 may be index-graded by causing it to a higher oxygen content (and thus a lower refractive index) at a portion therein closer to the TCO 3, and a lower oxygen content (and thus a higher refractive index) at a portion thereof farther from the TCO 3 and closer to the absorber 5; again, this oxidation grading may be either continuous or discontinuous in different examples of this invention. Being an integrated part of the layer stack of the photovoltaic device, the intermediate film 4 may be a robust anti-reflection (AR) film with additional possible barrier properties such as reduction in diffusion and the like. In certain example embodiments of this invention, the Nb-doped TiOₓ may include from about 0.1 to 25% Nb, more preferably from about 0.5 to 15% Nb, and most preferably from about 1-10% Nb.

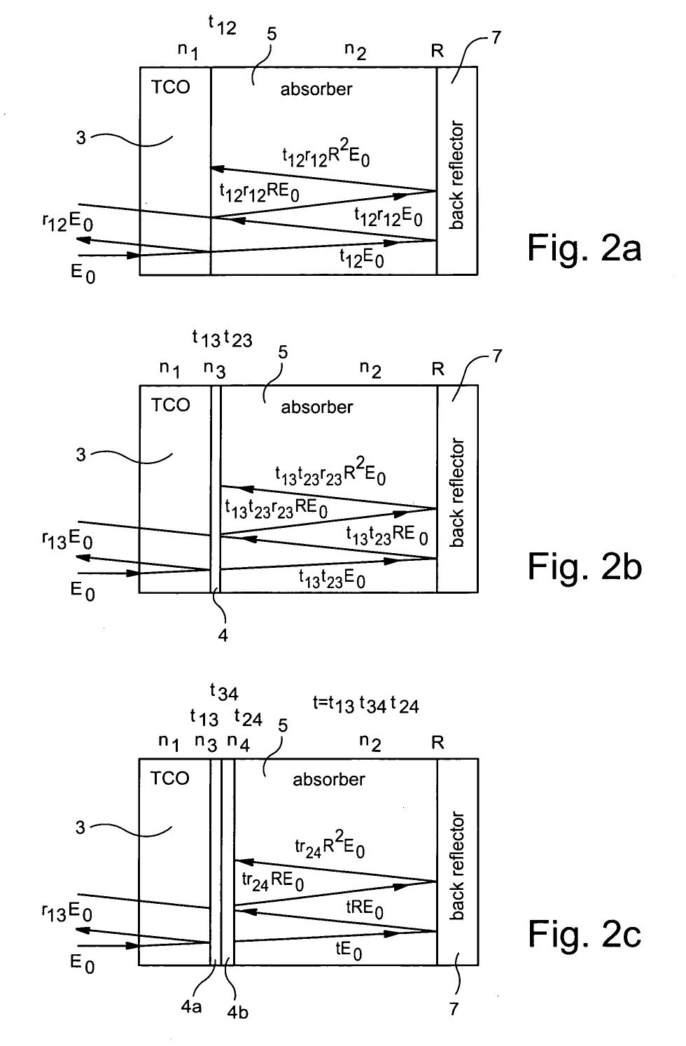

As mentioned above, the refractive index (n) of the intermediate film 4 can be tuned or designed so as to reduce optical reflection of solar radiation due to the TCO/absorber interface (i.e., interface between films 4 and 5) thereby enhancing the amount of radiation which penetrates the absorber and which can be converted into electrical energy so as to improve efficiency of the device. Disregarding film 4, there may be a high refractive index (n) mismatch between the TCO 3 and the absorber 5; this results in a high amount of solar radiation reflection from the TCO/absorber interface which in turn causes reduced device efficiency. The introduction of a discrete (non-graded) or graded intermediate film 4 with a tuned refractive index (n) that is higher than that of the TCO 3 and lower than that of the semiconductor absorber 5 reduces the amount of radiation (e.g., light) that is reflected and thus acts as an internal anti-reflective (AR) filter. For purposes of example and understanding, the refractive indices of ZnAlOx (an example of TCO 3) and a—Si:H (an example of absorber semiconductor 5) for solar wavelengths are about 1.9 (n1) and 4.0 (n2), respectively. Referring to FIG. 2(a), without intermediate film 4, this gives the amount of transmitted light reaching the absorber 5 from the TCO as in equation (1) below (note that E₀ is the amplitude of light impinging on the TCO/absorber interface from the glass 1 side):

I₁₂=(E₀t₁₂)²=[E₀(4n₁n₂/(n1+n₂)²)]²=[E₀(4×1.9×4.0/(1.9+4.0)²)]²=0.7627E₀² (1)

However, the incorporation of discrete intermediate film 4 with an example refractive index (n) of 2.4 results in the following increased amount of light reaching the absorber 5 as shown below in equation (2), referring to FIG. 2(b):

I₁₂=(E₀t₁₃t₂₃)²=[E₀(4n₁n₃/(n₁+n₃)²) (4n₂n₃/(n₂+n₃)²)]²=[E₀(4×1.9×2.4/(1.9+2.4)²) (4×4.0×2.4/(4.0+2.4)²)]^{2=0.8553}E₀² (2)

It will be appreciated that the increased amount of light reaching the absorber 5 (i.e., 0.8553E₀²) when intermediate film 4 is used (compared to only 0.7627E₀² when film 4 is not present) evidences about a 12% increase in efficiency and thus a significantly more efficient photovoltaic device. Referring to FIG. 2(c), when the intermediate film 4 includes two layers 4a and 4b, efficiency can also be increased.

As a second possible advantage associated with certain example embodiments of this invention, the refractive index (n) of the intermediate film 4 can be tuned or designed so as to increase the amount of radiation trapped within the semiconductor absorber 5 which can be converted into electrical energy, thereby improving efficiency of the photovoltaic device. In certain example embodiments, the provision of intermediate film 4 results in a redistribution of the intensity of solar radiation (e.g., light) reflected from the TCO/absorber interface toward the front of the photovoltaic device and the intensity of radiation (e.g., light) trapped within the semiconductor absorber film 5. The former can play a role in determining the amount of radiation reaching the absorber, while the latter can play a role in determining the amount of radiation participating in multiple reflections within the absorber 5 and thus dictating the efficiency of the device. This portion of radiation also has a probability to generate charge carriers. Generally speaking, the amplitude of solar light penetrating from the TCO 3 into the absorber 5 may be said to be

Eᵢₙ=t₁₂E₀ (3)

Taking into account the first and second order reflections from the back electrode 7 and the TCO 3/absorber 5 interface (see FIG. 2a), the amplitude of light within the absorber may be said to be:

Eᵢₙ=t₁₂E₀(1+R+r₁₂R+r₁₂R²)=t₁₂E₀(1+R)(1+r₁₂R) (4)

which gives the light intensity

Iᵢₙ=t₁₂²E₀²(1+R)²(1+r₁₂R)² (5)

When the intermediate film 4 is incorporated as shown in FIG. 2(b), the light intensity within the absorber becomes

Iᵢₙ=t₁₂²t₂₃²E₀²(1+R)²(1+r₂₃R)² (6)

Thin film photovoltaic devices such as solar cells typically exhibit rather low conversion efficiency due to a small absorption coefficient of the absorber 5; therefore, a reflective metal back contact 7 has often been used. Most metals used for back reflectors (e.g., Cr and Mo) reflect no more than about 25% of light at solar wavelengths of 600-700 nm. An Al back contact in a—Si:H solar cells may reflect about 75%, but can lead to degradation of the device.

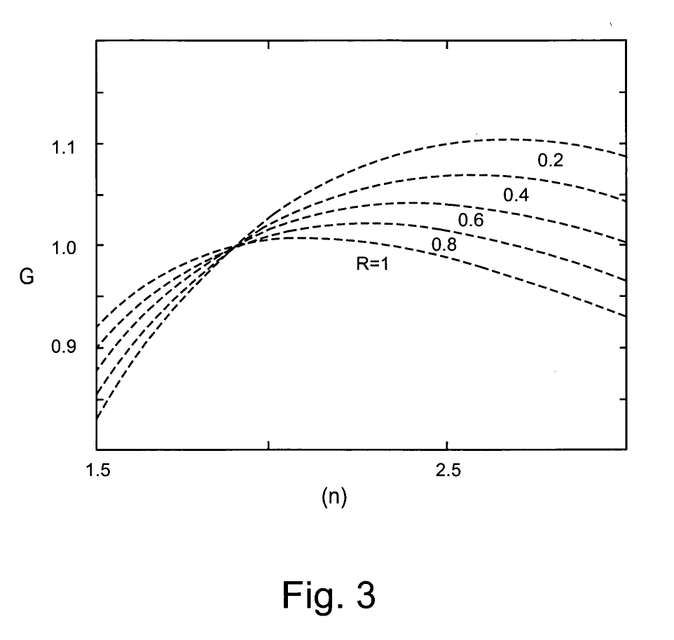

FIG. 3 demonstrates the ratio (G) of the amount of light trapped within the absorber 5 in the device with the intermediate film 4, compared to the device without the intermediate film 4. It is noteworthy that G increases when a less efficient back reflector is used. About 10% of light intensity can be achieved. At the same time, the maximum of G shifts toward higher values of refractive index (n) of the intermediate film 4. As the index (n) of the intermediate film 4 reaches about 2.0 and above, it can be seen that the ratio G advantageously increases thereby illustrating an increase in the amount of radiation trapped within the semiconductor absorber 5 which can be converted into electrical energy, thereby improving efficiency of the photovoltaic device. Moreover, because G increases when less efficient back reflectors (e.g., see 0.2 and 0.4 in FIG. 3), it is possible to realize an efficient photovoltaic device while either not using a back reflector or while using a less efficient but possibly more desirable back reflector of a material such as Cr and/or Mo.

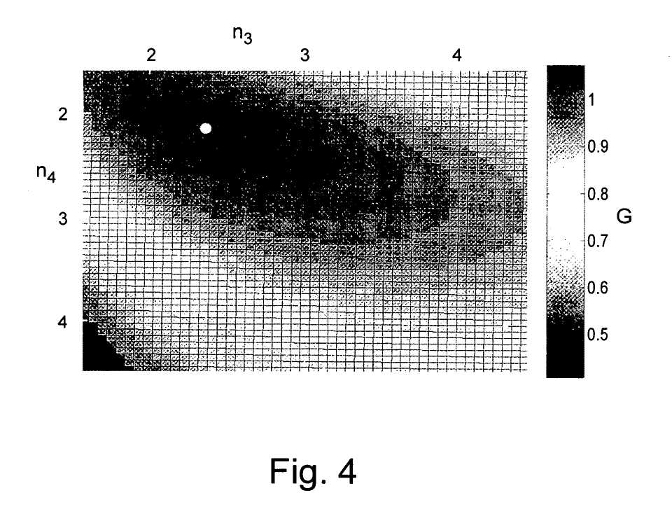

FIG. 4 is an example simulation of the results of optimization of a two-layer intermediate film 4 at the TCO/a—Si:H interface. It has been found that the optimal combination for the bi-layer intermediate film 4 for an example TCO/a—Si:H interface is for a first layer 4b having a refractive index (n) of from about 2.25 to 2.6, more preferably from about 2.3 to 2.55, with an example being about 2.4, and the second layer 4a having a lower refractive index of from about 2.0 to 2.25, more preferably from about 2.0 to 2.2, with an example being about 2.2. Note that second layer 4a with the lower refractive index is adjacent the TCO, and the layer 4b with the higher refractive index is adjacent and contacting the absorber 5. Additionally, index grading of the film 4 from the lower-index material (see TCO 3) to the higher-index material (see absorber 5) can further increase the amount of light trapped in absorber 5 which is advantageous.

Intermediate film 4 can also be advantageously used to reduce cross-diffusion of elements between the TCO 3 of the front contact and the absorbing semiconductor film 5 (e.g., to reduce cross diffusion of oxygen and hydrogen between films 3 and 5 in the example case where zinc oxide is used as the TCO 3 and a—Si:H is used in the absorber film 5). Certain types of solar cells (e.g., a—Si:H solar cells) use SnO2:F as a front transparent electrode or TCO 3. The use of tin oxide can lead to its darkening due to reduction in hydrogen atmosphere during the absorber deposition. Vacuum deposited ZnO doped with Group III elements is considered as a good a—Si:H TCO 3 candidate because of its resistance to hydrogen plasma reduction. There are other reasons, however, to avoid the exposure of ZnO to hydrogen during the a—Si:H deposition as well as to prevent the cross-diffusion of hydrogen and oxygen between the TCO and a—Si:H layers. The level of cross-diffusion is determined by the difference in chemical potentials between the two layers, or in other words, by the amount the energy of the system would change when an additional particle is introduced at the fixed entropy and volume. Hydrogen causes large lattice relaxation when introduced into ZnO, which is partially responsible for its rapid penetration in this material. At the same time, hydrogen is known to have very low activation energy of 0.17 eV in ZnO, which makes it diffusible in ZnO. Hydrogen forms unstable donor-like O—H complexes in ZnO, which eventually form H2 molecules, speculatively responsible for a drift in the device characteristics over time. On the other hand, hydrogen facilitates oxygen diffusion in the a—Si:H layer. This occurs according to a two-step mechanism; in the first step hydrogen opens up a Si—Si bond for oxygen atom, and in the second step it saturates a Si broken bond, thus decreasing the activation energy of oxygen diffusion. Cross-diffusion of hydrogen and oxygen cause band bending at the TCO/a—Si:H interface and, as a result, the formation of an additional potential barrier, which in turn reduces the device efficiency. The incorporation of the intermediate film 4 reduces cross-diffusion of atoms and ions between the TCO 3 and the absorber 5. Moreover, the use of intermediate film 4 also permits zinc oxide and/or tin oxide to be used as the TCO 3 without significantly suffering from the problems discussed above.

For purposes of example, in certain example embodiments of this invention, intermediate film 4 can be produced by incorporating a discrete TiNbOx transparent conducting film between a ZnO TCO 3 and an a—Si:H absorber 5. An example advantage of TiNbOx for film 4 is its high enthalpy of formation of about 940 kJ/mol, which makes it more stable in sense of oxygen release compared to ZnO (350 kJ/mol) or SnO2(581 kJ/mol), thereby permitting it to reduce diffusion as discussed above. Also, TiNbOx can have a desirable refractive index of from about 2.1 to 3.2, more preferably from about 2.15 to 2.75, with an example index (n) being about 2.4.

In certain example embodiments of this invention, intermediate film 4 may be designed so as to form a high resistivity buffer layer (HRBL) (e.g., in a CdS/CdTe based solar cell) between the front contact TCO 3 and the absorber film 5 in order to improve device performance. In certain example situations, the presence of a HRBL between the TCO 3 and the absorber 5 (e.g., CdS/CdTe absorber) may be desirable so as to enhance device performance and to provide at least some protection from shunting if there were to be pinholes in the CdS layer for example. In such cases, intermediate film 4, for example and without limitation, may be made of or include TiNbOx where the Nb dopant is either reduce or eliminated from the film 4 at or near the interface with the absorber. Other combinations of transparent conductive intermediate films 4 may also be used in different example embodiments of this invention.

While TiNbOx is mentioned above as a possible material for intermediate film 4, this invention is not so limited. Other materials may instead be used for film 4, so long as one, two, three or four of the aforesaid features (a) through (d) may be met. In particular, any suitable material of an appropriate refractive index or indices may be used for form film 4, so long as it is capable of resulting in one or more of the following: (a) reduce optical reflection of solar radiation due to the TCO/absorber interface (i.e., interface between films 4 and 5) thereby enhancing the amount of radiation which penetrates the absorber and which can be converted into electrical energy so as to improve efficiency of the device, (b) increase the amount of radiation trapped within the absorber 5 which can be converted into electrical energy, (c) reduce cross-diffusion of elements between the TCO 3 of the front contact and the absorbing semiconductor film 5, and/or (d) form a high resistivity buffer layer (HRBL) in certain cases between the front contact TCO 3 and the absorber film 5 in order to improve device performance.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A photovoltaic device comprising:
a front glass substrate;
a semiconductor film including p-type, n-type and i-type layers;
a substantially transparent conductive oxide (TCO) based film located between at least the front glass substrate and the semiconductor film; and
an intermediate film located between the TCO based film and the semiconductor film, wherein the intermediate film has a refractive index (n) that is higher than that of the TCO based film and lower than that of the semiconductor film.

2. The photovoltaic device of claim 1, wherein the intermediate film directly contacts each of the TCO based film and the semiconductor film.

3. The photovoltaic device of claim 1, wherein the refractive index (n) of the intermediate film is from about 2.0 to 4.0.

4. The photovoltaic device of claim 1, wherein the refractive index (n) of the intermediate film is from about 2.1 to 3.2.

5. The photovoltaic device of claim 1, wherein the refractive index (n) of the intermediate film is from about 2.15 to 2.75.

6. The photovoltaic device of claim 1, wherein the intermediate film is a semiconductor.

7. The photovoltaic device of claim 1, wherein the intermediate film comprises TiNbOₓ.

8. The photovoltaic device of claim 1, wherein the intermediate film comprises an oxide of titanium.

9. The photovoltaic device of claim 1, wherein the semiconductor film comprises amorphous silicon.

10. The photovoltaic device of claim 1, further comprising a conductive back electrode, wherein the semiconductor film is provided between at least the TCO based film and the back electrode.

11. The photovoltaic device of claim 1, wherein the intermediate film is index graded so that its index of refraction (n) varies, continuously or discontinuously, through its thickness.

12. The photovoltaic device of claim 1, wherein the TCO based film comprises one or both of zinc oxide and/or tin oxide.

13. The photovoltaic device of claim 1, wherein the intermediate film includes first and second layers with different first and second indices of refraction, respectively.

14. The photovoltaic device of claim 1, wherein the intermediate film is substantially transparent.

15. A photovoltaic device comprising:
a front glass substrate;
a semiconductor absorber film;
a substantially transparent conductive oxide (TCO) based film located between at least the front glass substrate and the semiconductor absorber film; and
an intermediate film located between the TCO based film and the semiconductor absorber film, wherein the intermediate film has a refractive index (n) of from about 2.0 to 4.0 and which is higher than that of the TCO based film and lower than that of the semiconductor absorber film.

16. The photovoltaic device of claim 15, wherein the refractive index (n) of the intermediate film is from about 2.1 to 3.2.

17. The photovoltaic device of claim 15, wherein the refractive index (n) of the intermediate film is from about 2.15 to 2.75.

18. The photovoltaic device of claim 15, wherein the intermediate film is a semiconductor.

19. The photovoltaic device of claim 15, wherein the intermediate film comprises Nb-doped TiOₓ.

20. The photovoltaic device of claim 15, wherein the intermediate film comprises an oxide of titanium.

21. The photovoltaic device of claim 15, wherein the refractive index (n) of the intermediate film varies, continuously or discontinuously, through its thickness.

22. The photovoltaic device of claim 15, wherein the TCO based film comprises one or both of zinc oxide and/or tin oxide.

23. The photovoltaic device of claim 15, wherein the intermediate film includes first and second layers with different first and second indices of refraction, respectively.

24. A method of making a photovoltaic device, the method comprising:
providing a substrate;
depositing a first substantially transparent conductive oxide (TCO) film on the substrate;
forming an intermediate film on the substrate over at least the TCO film, wherein the intermediate film has a refractive index (n) of from about 2.0 to 4.0 and which is higher than that of the TCO film; and
forming the photovoltaic device so that the intermediate film is located between the TCO film and a semiconductor film of the photovoltaic device.

25. The method of claim 24, wherein the refractive index (n) of the intermediate film is from about 2.15 to 2.75.

26. The method of claim 24, wherein the intermediate film comprises TiNbOₓ and/or an oxide of titanium.

27. The method of claim 24, wherein the refractive index (n) of the intermediate film varies, continuously or discontinuously, through its thickness.
